(19) United States
(12) Patent Application Publication
(10) Pub. No.: US 2001/0052640 A1
(43) Pub. Date: Dec. 20, 2001

(54) Solid image pickup device

(76) Inventor: Emiko Sekimoto, Kanagawa (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 09/803,255

(22) Filed: Mar. 9, 2001

(30) Foreign Application Priority Data
Mar. 9, 2000 (JP) P2000-064402

(51) Int. Cl. H01L 23/02

(52) U.S. Cl. 257/678

(57) ABSTRACT

A solid image pickup device is enclosed in an integral package comprising an upper package and a lower package, which are made of a resin and molded together with a lead frame held between the upper and lower packages, the device having outline references provided on lateral sides of the integral package. Tapered surfaces are formed along an overall side periphery of the upper package and an overall side periphery of the lower package. A plurality of holes are formed to penetrate the integral package in the vertical direction. Cutouts are formed on opposite lateral sides of the integral package to make parts of two parallel sides of the lead frame exposed to the outside, and the holes are formed in the parts of the lead frame exposed in the cutouts.

### RELATED APPLICATION DATA

The present application claims priority to Japanese Application No. P2000-064402 filed Mar. 9, 2000, which application is incorporated herein by reference to the extent permitted by law.

### BACKGROUND OF THE INVENTION

The present invention relates to a solid image pickup device, which has a package molded using a thermosetting or thermoplastic resin (hereinafter referred to as a “thermosetting resin, etc.”) and is accurately arranged by employing a package outline as a reference, i.e., positioned based on the so-called outline reference.

Hitherto, a solid image pickup device enclosed in a package made of a thermosetting resin, etc. has been mounted by employing outline references, i.e., several areas of side surfaces defining a package outline. For example, in the case of a solid image pickup device 1 having an image pickup surface 1a arranged parallel to a vertical plane in use as shown in FIG. 8A, side surfaces 3 appearing as viewed from the line VIIIB-VIIIB in a direction of arrows serve as reference surfaces in the horizontal direction, and a side surface 5 appearing as viewed from the line VIIIC-VIIIC in a direction of arrows serves as a reference surface in the vertical direction. In the package using those outline references, it has been required to mold the package such that the side surfaces 3, 5 cross the image pickup surface 1a at an exactly or nearly right angle, because the reference surfaces are provided in the side surfaces 3, 5.

Also, in the conventional solid image pickup device 1, as shown in FIGS. 9 and 10, an integral package 13 comprises an upper package 7 and a lower package 9, which are made of a thermosetting resin, etc. and are molded together with a lead frame 11 held between them. A hollow 15 having an upward opening is formed in the upper package 7 to provide a cavity 19 for accommodating a solid image pickup die 17 therein. The solid image pickup die 17 is fixed by die bonding to a resin-made die attachment 21 that is disposed, for example, at the recessed inner bottom of the lower package 9. A sealing glass 23 serving as an optically transparent cap is fixed to an upper surface of the upper package 7 to close the upward opening of the hollow 15. Furthermore, for the purpose of increasing airtightness of the package 13 in the solid image pickup device 1, the package 13 is made of a material having low moisture permeability and a sealant 25 is coated to cover boundaries between leads and the package.

The conventional solid image pickup device 1 having the above-described construction is additionally provided with a positioning and fixing part (hereinafter referred to as a “plate member”) for assembly, which is used as a positioning reference when the package 13 of the solid image pickup device 1 is assembled to a board, a lens, etc.

The assembly of the package 13 is performed as shown in FIG. 11. First, the solid image pickup device 1 and a plate member 27 are joined to each other. Then, pins 33 provided on a lens barrel 31 are inserted through positioning holes 27a, 29a, which are formed respectively in the plate member 27 and a board 29, for positioning of the plate member 27 and the solid image pickup device 1. Then, screws 37 are inserted through screw insertion holes 29b, 27b, which are formed respectively in the board 29 and the plate member 27, and are tightened into the lens barrel 31. The lens barrel 31, the plate member 27 and the board 29 are thereby fixed together.

In such a conventional solid image pickup device, however, the side surfaces of the package must be formed so as to cross the image pickup surface at an exactly or nearly right angle, because the side surfaces of the package are employed as outline references. This necessity has raised a problem that the upper package 7 and the lower package 9 are hard to part away from molds 39, 41 respectively in the package manufacturing process shown in FIG. 12, thus resulting in a reduction of moldability and productivity.

Also, using a material having low moisture permeability to form the package for increasing airtightness of the package pushes up the material cost as compared with the case of using materials for general purpose use. Coating a sealant to cover boundaries between leads and the package increases airtightness of the package to a certain extent, but cannot sufficiently prevent moisture from entering the package from a rear surface of the lower package.

Further, in the conventional solid image pickup device, since the solid image pickup die is fixed by die bonding to the resin-made die attachment that is disposed, for example, at the recessed inner bottom of the lower package, a problem has been experienced in that thermal conductivity is low and heat generated from the solid image pickup die is hard to dissipate to the outside of the package.

Moreover, since the optically transparent cap is fixed to the upper surface of the upper package by an adhesive coated on it, proper positioning of the cap free from a θ-deviation about an axis vertical to a light passing surface of the cap is not ensured, and therefore an optical filter having anisotropy and requiring to be positioned with high accuracy cannot be employed as the cap. For this reason, a sealing glass must be employed, and this necessity has impeded a reduction of the package thickness.

Still another problem is that, since the package must be additionally associated with the plate member to provide positioning references for assembly of the package to a board, a lens, etc., the overall size of the solid image pickup device is increased.

### SUMMARY OF THE INVENTION

In view of the state of the art set forth above, it is an object of the present invention to provide a solid image pickup device, which can improve moldability, productivity, airtightness and heat radiation, and which can reduce a device thickness, thereby realizing higher quality and a cost cut-down of the solid image pickup device.

To achieve the above object, according to the present invention, in a solid image pickup device enclosed in an integral package comprising an upper package and a lower package, which are made of a resin and molded together with a lead frame held between the upper and lower packages, the device further comprises tapered surfaces formed along an overall side periphery of the upper package and an overall side periphery of the lower package, and a plurality of holes penetrating the integral package in the vertical direction.

In the solid image pickup device of the present invention, since the tapered surfaces are formed along the overall side periphery of the upper package and the overall side periphery of the lower package, it is possible to easily release the upper package from an upper mold and the lower package from a lower mold when the integral package is molded. Also, a plurality of holes are formed to penetrate the integral package in the vertical direction and are employed as references for positioning the integral package. Accordingly, external exposed parts of the integral package can be employed as outline references for positioning of the integral package while allowing the upper package and the lower package to be easily released from the molds.

Preferably, cutouts are formed on opposite lateral sides of the integral package to make parts of two parallel sides of the lead frame exposed to the outside, and the plurality of holes are formed in the parts of the lead frame exposed in the cutouts on the opposite lateral sides of the integral package.

In the solid image pickup device having the above features, the holes are formed in the lead frame to which a solid image pickup die is fixed, and are exposed to the outside by the presence of the cutouts formed in the integral package. By employing those holes as outline references, the solid image pickup die can be arranged by direct positioning and accuracy in optical positioning of the solid image pickup device can be increased. Also, the direct positioning and fixing of the solid image pickup device can be realized by employing the holes, and therefore additional parts for positioning and fixing the solid image pickup device are no longer required.

Preferably, a hollow having an upward opening and formed in the upper package provides a cavity for accommodating a solid image pickup die, and a sealing resin is filled in the cavity except for an area above an image pickup surface of the solid image pickup die.

In the solid image pickup device having the above features, the sealing resin is filled in the cavity except for the area above the image pickup surface of the solid image pickup die so that the solid image pickup die is made integral with the package through the sealing resin while it is sealed off by the same. This structure is effective in preventing moisture from entering the device through not only boundaries between the leads and the package, but also a bottom portion of the lower package, and hence increasing airtightness for protection of the solid image pickup die. Furthermore, since the sealing resin filled in the hollow is hardened in union with the package, the strength of the package can be increased.

Preferably, the sealing resin is opaque to image pickup light.

In the solid image pickup device having the above feature, the wires, such as gold wires, connecting inner leads and the solid image pickup die are embedded in the opaque sealing resin filled in the hollow. Therefore, flares causing, e.g., white blurs of an image can be prevented from occurring due to light incoming through the upward opening of the hollow and entering, in addition to normal light, the image pickup surface after diffused reflection of the light at the wires.

Preferably, inner leads of the lead frame are arranged in the cavity and positioned at a lower level than the image pickup surface of the solid image pickup die.

In the solid image pickup device having the above feature, since the inner leads of the lead frame are positioned at a lower level than the image pickup surface of the solid image pickup die, most parts of the wires for electrically connecting the inner leads and the solid image pickup die are covered by the sealing resin, and hence the occurrence of flares can be more surely prevented.

Preferably, the solid image pickup die is directly fixed to a die attachment on the lead frame.

In the solid image pickup device having the above feature, since the solid image pickup die is directly fixed to the die attachment disposed on the lead frame, heat generated from the solid image pickup die is directly conducted to the lead frame. Then, the heat conducted to the lead frame is radiated to the outside from the parts of the lead frame exposed in the cutouts. In addition, the heat conducted to the lead frame is further conducted to an external member, which is fixedly attached through the exposed parts of the lead frame. As a result, effective heat radiation is achieved.

Preferably, an optical filter is disposed in the upward opening of the hollow formed in the upper package.

In the solid image pickup device having the above feature, since the optical filter is disposed in the upward opening of the hollow formed in the upper package, the overall thickness of the device can be reduced as compared with the case of attaching a sealing glass to the upper surface of the integral package.

Preferably, a step for fitting to the optical filter is provided on an inner periphery of the hollow.

In the solid image pickup device having the above feature, since the optical filter is fitted to the step provided on the inner periphery of the hollow, the optical filter can be properly positioned about an axis vertical to a light passing surface of the optical filter, and therefore a θ-deviation of the optical filter having anisotropy can be suppressed when it is positioned.

### BRIEF DESCRIPTION OF THE DRAWINGS

FIG. 1 is a plan view of a solid image pickup device according to the present invention;

FIG. 2 is a side view as viewed from the line II-II of FIG. 1 in a direction of arrows;

FIG. 3 is a side view as viewed from the line III-III of FIG. 1 in a direction of arrows;

FIG. 4 is a sectional view taken along the line IV-IV of FIG. 1;

FIG. 5 is a sectional view taken along the line V-V of FIG. 1;

FIG. 6 is an exploded perspective view for explaining steps of assembling the solid image pickup device shown in FIG. 1, a board, and a lens barrel;

FIG. 7 is an explanatory view showing a condition where a package of the solid image pickup device shown in FIG. 1 is molded using molds;

FIGS. 8A, 8B and 8C show an outward appearance of a conventional solid image pickup device; i.e., FIG. 8A is a plan view, FIG. 8B is a side view as viewed from the line VIIIB-VIIIB of FIG. 8A in a direction of arrows, and FIG. 8C is a side view as viewed from the line VIIIC-VIIIC of FIG. 8A in a direction of arrows;

FIG. 9 is an enlarged plan view of the conventional solid image pickup device;

FIG. 10 is a sectional view taken along the line X-X in FIG. 9;

FIG. 11 is an exploded perspective view for explaining steps of assembling the conventional solid image pickup device, a board, and a lens barrel; and

FIG. 12 is an explanatory view showing a condition where a package of the conventional solid image pickup device is molded using molds.

### DESCRIPTION OF THE PREFERRED EMBODIMENTS

A preferred embodiment of a solid image pickup device according to the present invention will be described below in detail with reference to the drawings.

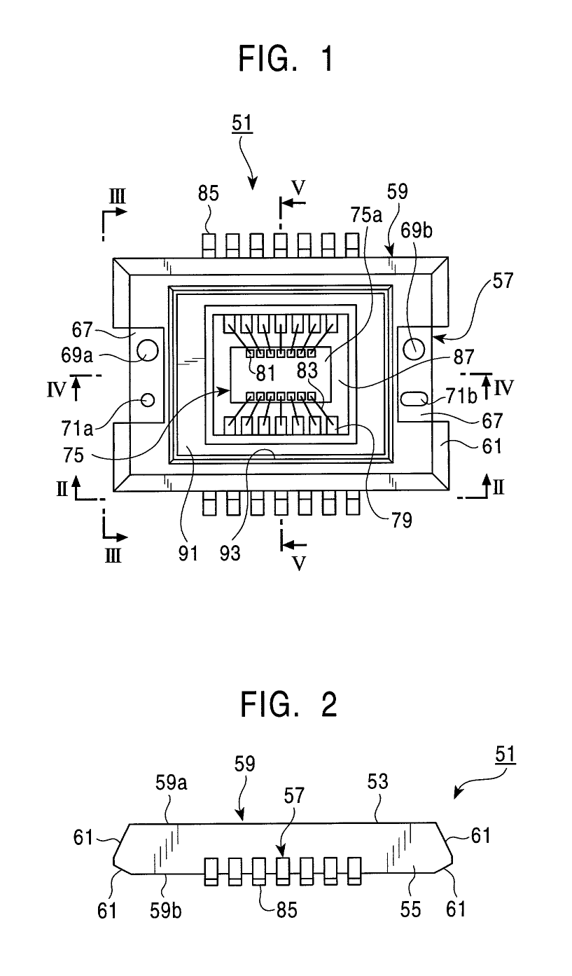

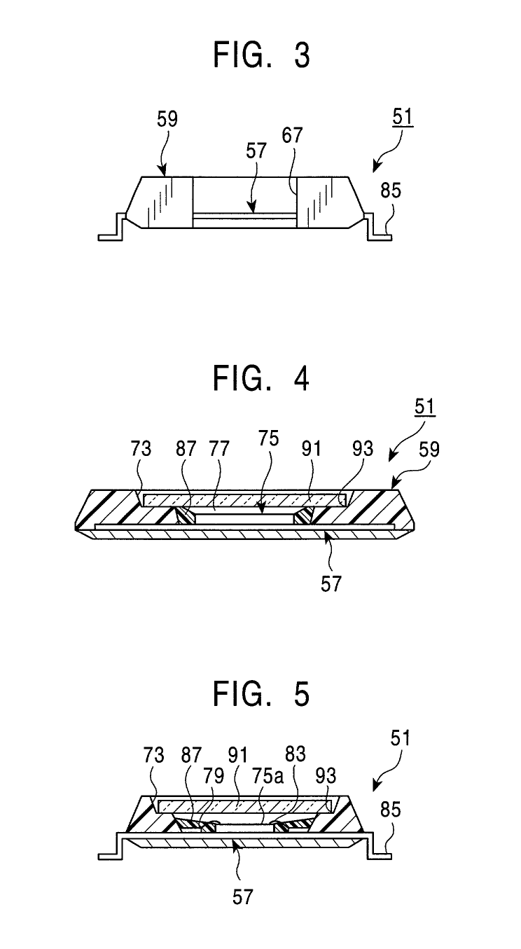

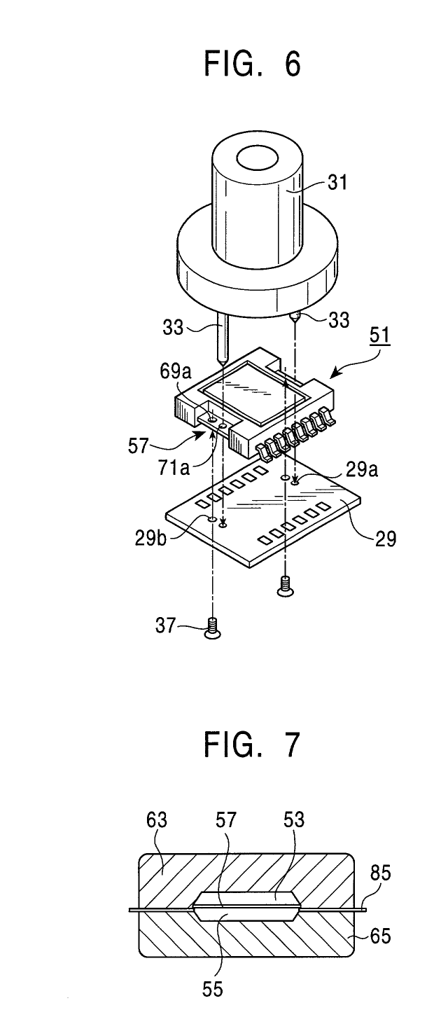

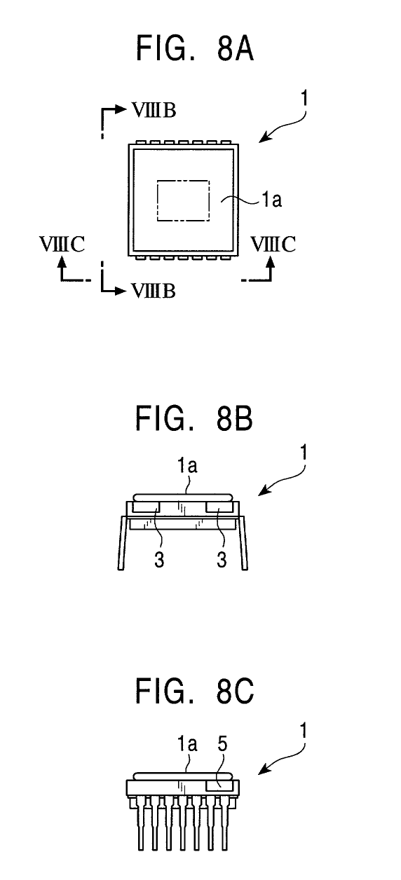

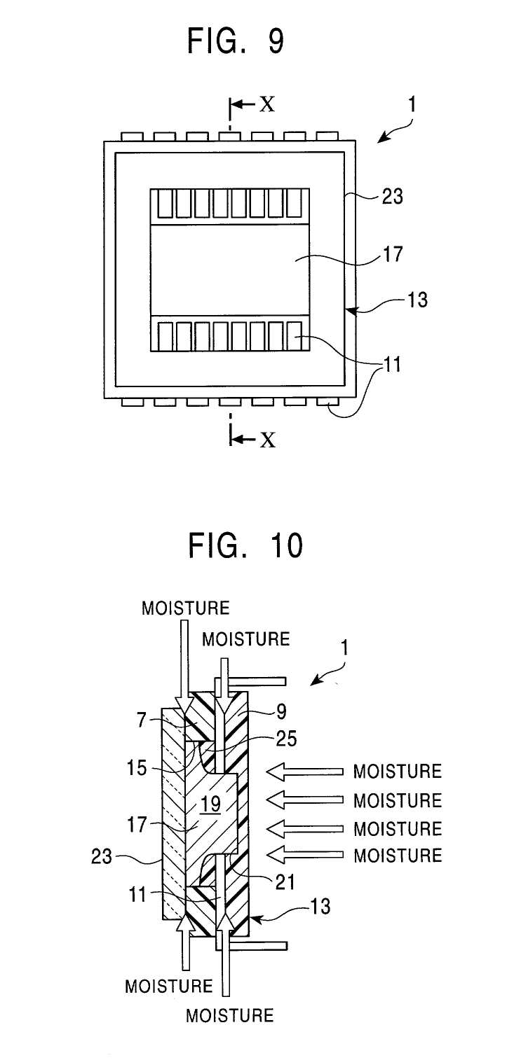

FIG. 1 is a plan view of the solid image pickup device according to the present invention; FIG. 2 is a side view as viewed from the line II-II of FIG. 1 in a direction of arrows; FIG. 3 is a side view as viewed from the line III-III of FIG. 1 in a direction of arrows; FIG. 4 is a sectional view taken along the line IV-IV of FIG. 1; FIG. 5 is a sectional view taken along the line V-V of FIG. 1; FIG. 6 is an exploded perspective view for explaining steps of assembling the solid image pickup device shown in FIG. 1, a board, and a lens barrel; and FIG. 7 is an explanatory view showing a condition where a package of the solid image pickup device shown in FIG. 1 is molded using molds.

A solid image pickup device 51 of this embodiment is enclosed in an integral package 59 comprising an upper package 53 and a lower package 55, which are made of a thermosetting resin, etc. and are molded together with a lead frame 57 held between them. The solid image pickup device 51 includes positioning references provided on lateral sides of the package 59 as described later.

Tapered surfaces 61 are formed along an overall side periphery of the upper package 53 and an overall side periphery of the lower package 55. The tapered surfaces 61 are inclined in such directions as allowing the upper package 53 and the lower package 55 to be easily released from an upper mold 63 and a lower mold 65, respectively, which are employed to mold the upper package 53 and the lower package 55 as shown in FIG. 7. In other words, the upper mold 63 and the lower mold 65 are each fabricated to have a draft provided by setting an opening area of a mold cavity on the side, from which a molded product is drawn out, to be greater than a bottom area of the mold cavity. In general, the tapered surfaces 61 are preferably inclined at an angle in the range of 5-10 degrees. For reducing an overall thickness of the device, the lower package 55 is molded to form a bottom portion with a thickness of 0.2-0.8 mm.

The package 59 of the solid image pickup device 51 has a plurality of holes penetrating the package in the vertical direction. More specifically, in this embodiment, cutouts 67 are formed on opposite lateral sides of the package 59 so that parts of two parallel sides of the lead frame 57 are exposed to the outside. Two pairs of holes are formed in those parts of the lead frame 57 exposed in the cutouts 67. These two pairs of holes provide the plurality of holes penetrating the package in the vertical direction. One pair of holes serve as screw insertion holes 69a, 69b, and the other pair of holes serve as positioning holes 71a, 71b. Of the positioning holes 71a, 71b, one 71a serves as a reference hole and the other 71b serves as an elongate guide hole. Thus, the positioning holes 71a, 71b are employed as references for positioning the package in the length and width directions. Also, an upper surface 59a and a rear surface 59b defining an outline of the package 59, shown in FIG. 2, are employed as references for positioning the package in the vertical direction. Accuracy in optical positioning of the package 59 with the positioning holes 71a, 71b is within ±40 μm for the ¼ type and within ±30 μm for the ⅙ type.

A stepped hollow 73 having an upward opening is formed in the upper package 53 to provide a cavity 77 for accommodating a solid image pickup die 75 therein. The lead frame 57 is exposed to a bottom opening of the cavity 77. A die attachment (not shown) is disposed at the center of the lead frame 57, and the solid image pickup die 75 is directly fixed to the die attachment.

Inner leads 79 of the lead frame 57 are exposed to the bottom opening of the cavity 77. As shown in FIG. 5, the inner leads 79 are positioned at a lower level than an image pickup surface 75a of the solid image pickup die 75 attached to the die attachment. A plurality of bonding pads 81 are provided on an upper surface of the solid image pickup die 75. The bonding pads 81 are connected to the corresponding inner leads 79 by wires 83 such as gold wires. The inner leads 79 are electrically connected to outer leads 85 for connection to an external circuit.

A sealing resin 87 is partly filled in the cavity 77 except for an area above the image pickup surface 75a of the solid image pickup die 75. The sealing resin 87 is preferably opaque to, in particular, light incident upon the image pickup surface 75a. Most parts of the wires 83 connecting the bonding pads 81 and the inner leads 79 are therefore embedded in and covered by the sealing resin 87.

An optically transparent cap is disposed in the upper opening of the stepped hollow 73 formed in the upper package 53. In this embodiment, an optical filter 91 is disposed as the optically transparent cap. A step 93 for fitting to the optical filter 91 is formed on an inner periphery of the stepped hollow 15. The optical filter 91 is fitted to the step 93 and fixed in a properly positioned state by an adhesive applied to it. With this arrangement, the optical filter 91 can be attached free from a θ-deviation about an axis vertical to a light passing surface of the optical filter. The cavity 77 defined by the hollow 73 is hermetically sealed off by the optical filter 91 being disposed on the step 93. A low-pass filter or an infrared cut filter may be employed as the optical filter 91. In addition, a sealing glass, a polarizing filter, a color filter, a lens sheet or the like may be disposed as the optically transparent cap.

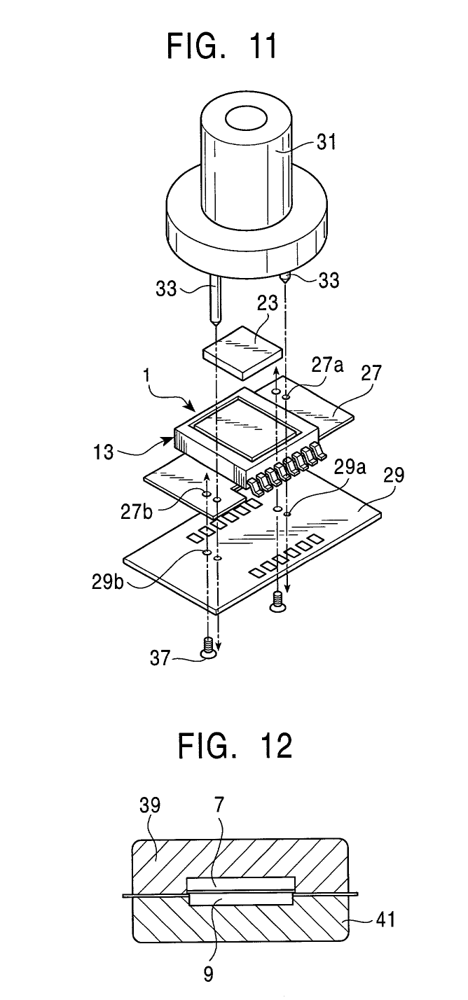

When assembling the solid image pickup device 51 having the above-described construction to a board, a lens, etc., the package 59 is directly assembled onto the board without using the plate member 27 (see FIG. 11), which has been conventionally used for positioning of the package.

More specifically, as shown in FIG. 6, pins 33 provided on a lens barrel 31 are inserted through the positioning holes 71a, 71b formed in the lead frame 57 and positioning holes 29a formed in a board 29 for positioning of the solid image pickup device 51. Then, screws 37 are inserted through screw insertion holes 29b formed in the board 29 and the screw insertion holes 69b, 69b formed in the lead frame 57, and tightened into the lens barrel 31. The lens barrel 31, the solid image pickup device 51 and the board 29 are thereby fixed together.

Thus, with the solid image pickup device 51 of this embodiment, the tapered surfaces 61 are formed along the overall side periphery of the package 59, the lead frame 57 is partly exposed to the outside in the cutouts 67 formed in the package 59, and the screw insertion holes 69a, 69b and the positioning holes 71a, 71b are formed in the exposed lead frame 57. Therefore, external exposed parts of the package 59 can be employed as outline references for positioning of the package 59 while allowing the upper package 53 and the lower package 55, which are molded together into the package 59, to be easily released from the molds.

Further, since the positioning holes 71a, 71b formed in the lead frame 57 are employed as the outline references, the solid image pickup die 75 can be disposed by direct positioning and accuracy in optical positioning of the solid image pickup device 51 can be increased. Also, since the package 59 is directly fixed using the screw insertion holes 69a, 69b, additional parts for fixing the package 59 are no longer required. As a result, it is possible to cut down the number of parts, the number of assembly steps and the cost, and to achieve a reduction of the overall device size.

In addition, since the sealing resin 87 is partly filled in the cavity 77, the solid image pickup die 75 can be made integral with the package 59 through the sealing resin 87 while it is sealed off by the same. This structure is effective in preventing moisture from entering the device through not only boundaries between the leads and the package 59, but also a bottom portion of the lower package 55, and hence increasing airtightness for protection of the solid image pickup die 75. Furthermore, since the sealing resin 87 filled in the hollow 73 is hardened in union with the package 59, the strength of the package 59 can be increased.

Since the wires 83 connecting the inner leads 79 and the solid image pickup die 75 are embedded in the sealing resin 87 filled in the hollow 73, an image can be prevented from being affected by flares caused upon diffused reflection light from the wires 83 entering the image pickup surface 75a.

Since the inner leads 79 are positioned at a lower level than the image pickup surface 75a of the solid image pickup die 75, most parts of the wires 83 can be covered by the sealing resin 87 and the occurrence of flares can be more surely prevented.

Since the solid image pickup die 75 is directly fixed to the die attachment disposed on the lead frame 57, heat generated from the solid image pickup die 75 can be directly conducted to the lead frame 57. Then, the heat conducted to the lead frame 57 can be radiated to the outside from the parts of the lead frame 57 exposed in the cutouts 67. In addition, the heat conducted to the lead frame 57 can be further conducted to an external member, which is fixedly attached through parts of the lower package 55 also exposed in the cutouts 67. As a result, effective heat radiation is achieved.

Since the optical filter 91 is disposed in the upper opening of the package 59, the overall thickness of the device can be reduced as compared with the case of attaching a sealing glass to the upper surface of the package.

Since the optical filter 91 is fitted for positioning thereof to the step 93 provided on the inner periphery of the hollow 73, the optical filter 91 can be properly positioned about the axis vertical to the light passing surface of the optical filter, and therefore a θ-deviation of the optical filter 91 having anisotropy can be suppressed when it is positioned.

The solid image pickup device 51 of this embodiment has been described above as forming the screw insertion holes 69a, 69b and the positioning holes 71a, 71b in the parts of the lead frame 57 exposed in the cutouts 67. Those holes, however, may be formed in the package 59 per se. In such a case, the holes can be formed, for example, at the same time as when the package 59 is molded, by preparing molds designed to form the holes, pouring a resin as a material of the package 59 to fill a mold cavity including portions corresponding to the cutouts 67 except for the holes, and releasing a molded package from the molds.

According to the solid image pickup device of the present invention, as described above in detail, tapered surfaces are formed along an overall side periphery of an upper package and an overall side periphery of a lower package, and a plurality of holes are formed to vertically penetrate an integral package comprising the upper and lower packages molded together. Therefore, external exposed parts of the integral package can be employed as outline references for positioning of the integral package while allowing the upper package and the lower package to be easily released from molds. As a result, moldability and productivity of the integral package can be increased without deteriorating accuracy in positioning of the integral package.

What is claimed is:

1. A solid image pickup device enclosed in an integral package comprising an upper package and a lower package, which are made of a resin and molded together with a lead frame held between said upper and lower packages, said device further comprising:
tapered surfaces formed along an overall side periphery of said upper package and an overall side periphery of said lower package; and
a plurality of holes penetrating said integral package in the vertical direction.

2. A solid image pickup device according to claim 1, wherein cutouts are formed on opposite lateral sides of said integral package to make parts of two parallel sides of said lead frame exposed to the outside, and
said plurality of holes are formed in the parts of said lead frame exposed in said cutouts on the opposite lateral sides of said integral package.

3. A solid image pickup device according to claim 1 or 2, wherein a hollow having an upward opening and formed in said upper package provides a cavity for accommodating a solid image pickup die, and
a sealing resin is filled in said cavity except for an area above an image pickup surface of said solid image pickup die.

4. A solid image pickup device according to claim 3, wherein said sealing resin is opaque to image pickup light.

5. A solid image pickup device according to claim 3, wherein inner leads of said lead frame are arranged in said cavity and positioned at a lower level than the image pickup surface of said solid image pickup die.

6. A solid image pickup device according to claim 2, wherein said solid image pickup die is directly fixed to a die attachment on said lead frame.

7. A solid image pickup device according to claim 1, wherein an optical filter is disposed in the upward opening of said hollow formed in said upper package.

8. A solid image pickup device according to claim 7, wherein a step for fitting to said optical filter is provided on an inner periphery of said hollow.
